(19) United States
(12) Patent Application Publication
(10) Pub. No.: US 2011/0081776 A1
(43) Pub. Date: Apr. 7, 2011

(54) METHOD FOR MANUFACTURING SEMICONDUCTOR DEVICE

(76) Inventors: Kotaro NOMURA, Toyama (JP); Makoto Tsutsue, Toyama (JP)

(21) Appl. No.: 12/822,782

(22) Filed: Jun. 24, 2010

(30) Foreign Application Priority Data
Oct. 6, 2009 (JP) 2009-232637

(51) Int. Cl. H01L 21/768

(52) U.S. Cl. 438/666; 257/E21.576

(57) ABSTRACT

A first insulating film is formed on or above a substrate, and a first conductor is formed in an upper portion of the formed first insulating film. Then, a second insulating film is formed on the first insulating film so as to cover the first conductor. Then, a film quality alteration process is performed for the second insulating film. Moreover, a third insulating film is formed on the second insulating film, and a curing process is performed for the formed third insulating film.

### CROSS-REFERENCE TO RELATED APPLICATION

This application claims priority to Japanese Patent Application No. 2009-232637 filed on Oct. 6, 2009, the disclosure of which including the specification, the drawings, and the claims is hereby incorporated by reference in its entirety.

### BACKGROUND

The present invention relates to a method for manufacturing a semiconductor device, and particularly to a method for manufacturing a semiconductor device including a metal conductor made of copper, or the like, and an inter-layer dielectric which is a low-dielectric-constant film.

In recent years, because of an increase in the density of conductor patterns due to an increase in the degree of integration of semiconductor integrated circuits, the parasitic capacitance between conductors has increased, causing a signal delay. Therefore, for a semiconductor integrated circuit required to operate at a high speed, there is a demand for a decrease in the parasitic capacitance between conductors. In view of this, currently, the dielectric constant of the inter-layer dielectric has been lowered in order to reduce the parasitic capacitance between conductors.

Conventionally, a silicon oxide film (SiO₂ film) (dielectric constant: 3.9-4.2), a fluorine (F)-containing SiO₂ film (dielectric constant: 3.5-3.8), or the like, has often been used as an insulating film between conductors. In some semiconductor integrated circuits, a carbon-containing silicon oxide film (SiOC film) has been used, and there has also been suggested a technique for further lowering the dielectric constant of the SiOC film by performing an ultraviolet irradiation (UV curing) process after the deposition of the SiOC film.

However, if a UV curing process is performed after the deposition of a low-dielectric-constant film which is the SiOC film, the insulating film underlying the low-dielectric-constant film is also subjective to the UV irradiation, damaging the insulating film underlying the low-dielectric-constant film. In view of this problem, Japanese Published Patent Application No. 2006-165573, for example, describes a method in which a protection film (a UV blocking film) is formed so that the UV light is less likely to pass through to layers underlying the low-dielectric-constant film.

### SUMMARY

However, with the conventional method for manufacturing a semiconductor device, during the UV curing process for the low-dielectric-constant film, the UV blocking film formed under the low-dielectric-constant film is exposed to the UV light. This results in an increase in the tensile component of the film stress of the UV blocking film exposed to the UV light. Here, if a portion of the UV blocking film is used as a film on the surface of a conductor (a liner film), this means an increase in the tensile component of the film stress of the liner film, which lowers the adhesion between the liner film and the underlying film, leading to an interfacial peeling between the liner film and the underlying film. As result, there arise new problems, i.e., a decrease in the production yield and a decrease in the reliability of the semiconductor device.

The present invention has been made in view of the problems in the prior art, and has an object to obtain a semiconductor device with a high reliability having a conductor structure of a high production yield by preventing, without using a UV blocking film, the interfacial peeling between a liner film, which is formed under a low-dielectric-constant film and over a conductor, and a film underlying the liner film, due to a UV curing process for the low-dielectric-constant film.

In order to achieve the object above, the present invention provides a method for manufacturing a semiconductor device in which a liner film formed under a low-dielectric-constant film and over a conductor is subjected, before the deposition of the low-dielectric-constant film, an alteration process for altering the film quality of the liner film.

Specifically, a method for manufacturing a semiconductor device of the present invention includes the steps of: (a) forming a first insulating film on or above a substrate, and forming a first conductor in an upper portion of the formed first insulating film; (b) forming a second insulating film on the first insulating film so as to cover the first conductor; (c) performing a film quality alteration process for the second insulating film; and (d) forming a third insulating film on the second insulating film, and performing a curing process for the formed third insulating film, after the step (c).

With the method for manufacturing a semiconductor device of the present invention, it is possible to reduce the influence of the curing process for the third insulating film on the second insulating film, and it is therefore possible to prevent an increase in the tensile component of the film stress of the second insulating film. As a result, it is possible to obtain a semiconductor device with a high reliability having a conductor structure of a high production yield.

In the method for manufacturing a semiconductor device of the present invention, it is preferred that the second insulating film is made of nitrogen-containing silicon carbide.

In such a case, it is preferred that a ratio of a silicon atom-hydrogen atom chemical bond quantity with respect to a silicon atom-carbon atom chemical bond quantity in the second insulating film is 2.5% or more and 3.0% or less.

In such a case, it is preferred that a ratio of a silicon atom-methyl group chemical bond quantity with respect to a silicon atom-carbon atom chemical bond quantity in the second insulating film is 0.2% or more and 0.4% or less.

Where the second insulating film is made of nitrogen-containing silicon carbide, it is preferred that a ratio of a silicon atom-hydrogen atom chemical bond quantity with respect to a silicon atom-carbon atom chemical bond quantity in an upper portion of the second insulating film is lower than that in a lower portion of the second insulating film, and a rate of change therebetween is 36% or less.

Where the second insulating film is made of nitrogen-containing silicon carbide, it is preferred that a ratio of a silicon atom-methyl group chemical bond quantity with respect to a silicon atom-carbon atom chemical bond quantity in an upper portion of the second insulating film is lower than that in a lower portion of the second insulating film, and a rate of change therebetween is 39% or less.

Where the second insulating film is made of nitrogen-containing silicon carbide, it is preferred that a ratio of a silicon atom-hydrogen atom chemical bond quantity with respect to a silicon atom-carbon atom chemical bond quantity in a portion of the second insulating film on the first conductor is lower than or equal to that in a portion of the second insulating film on the first insulating film, and a ratio therebetween is 0.85 or more and 1.00 or less.

Where the second insulating film is made of nitrogen-containing silicon carbide, it is preferred that a ratio of a silicon atom-methyl group chemical bond quantity with respect to a silicon atom-carbon atom chemical bond quantity in a portion of the second insulating film on the first conductor is less than or equal to that in a portion of the second insulating film on the first insulating film, and a ratio therebetween is 0.55 or more and 1.00 or less.

In the method for manufacturing a semiconductor device of the present invention, it is preferred that the second insulating film is made of oxygen-containing silicon carbide.

In such a case, it is preferred that a ratio of a silicon atom-hydrogen atom chemical bond quantity with respect to a silicon atom-carbon atom chemical bond quantity in the second insulating film is 10.0% or more and 12.0% or less.

In such a case, it is preferred that a ratio of a silicon atom-methyl group chemical bond quantity with respect to a silicon atom-carbon atom chemical bond quantity in the second insulating film is 1.0% or more and 1.8% or less.

In such a case, it is preferred that a ratio of a silicon atom-oxygen atom chemical bond quantity with respect to a silicon atom-carbon atom chemical bond quantity in the second insulating film is 49.0% or more and 56.0% or less.

In such a case, it is preferred that a ratio of a silicon atom-hydrogen atom chemical bond quantity with respect to a silicon atom-oxygen atom chemical bond quantity in the second insulating film is 19.0% or more and 24.0% or less.

Where the second insulating film is made of oxygen-containing silicon carbide, it is preferred that a ratio of a silicon atom-hydrogen atom chemical bond quantity with respect to a silicon atom-carbon atom chemical bond quantity in an upper portion of the second insulating film is lower than that in a lower portion of the second insulating film, and a rate of change therebetween is 14% or less.

Where the second insulating film is made of oxygen-containing silicon carbide, it is preferred that a ratio of a silicon atom-methyl group chemical bond quantity with respect to a silicon atom-carbon atom chemical bond quantity in an upper portion of the second insulating film is lower than that in a lower portion of the second insulating film, and a rate of change therebetween is 41% or less.

Where the second insulating film is made of oxygen-containing silicon carbide, it is preferred that a ratio of a silicon atom-oxygen atom chemical bond quantity with respect to a silicon atom-carbon atom chemical bond quantity in an upper portion of the second insulating film is higher than that in a lower portion of the second insulating film, and a rate of change therebetween is 52% or less.

Where the second insulating film is made of oxygen-containing silicon carbide, it is preferred that a ratio of a silicon atom-hydrogen atom chemical bond quantity with respect to a silicon atom-oxygen atom chemical bond quantity in an upper portion of the second insulating film is lower than that in a lower portion of the second insulating film, and a rate of change therebetween is 44% or less.

Where the second insulating film is made of oxygen-containing silicon carbide, it is preferred that a ratio of a silicon atom-hydrogen atom chemical bond quantity with respect to a silicon atom-carbon atom chemical bond quantity in a portion of the second insulating film on the first conductor is less than or equal to that in a portion of the second insulating film on the first insulating film, and a ratio therebetween is 0.95 or more and 1.00 or less.

Where the second insulating film is made of oxygen-containing silicon carbide, it is preferred that a ratio of a silicon atom-methyl group chemical bond quantity with respect to a silicon atom-carbon atom chemical bond quantity in a portion of the second insulating film on the first conductor is less than or equal to that in a portion of the second insulating film on the first insulating film, and a ratio therebetween is 0.45 or more and 1.00 or less.

Where the second insulating film is made of oxygen-containing silicon carbide, it is preferred that a ratio of a silicon atom-oxygen atom chemical bond quantity with respect to a silicon atom-carbon atom chemical bond quantity in a portion of the second insulating film on the first conductor is greater than or equal to that in a portion of the second insulating film on the first insulating film, and a ratio therebetween is 1.00 or more and 1.10 or less.

Where the second insulating film is made of oxygen-containing silicon carbide, it is preferred that a ratio of a silicon atom-hydrogen atom chemical bond quantity with respect to a silicon atom-oxygen atom chemical bond quantity in a portion of the second insulating film on the first conductor is less than or equal to that in a portion of the second insulating film on the first insulating film, and a ratio therebetween is 0.80 or more and 1.00 or less.

In the method for manufacturing a semiconductor device of the present invention, the second insulating film has a layered structure of nitrogen-containing silicon carbide and oxygen-containing silicon carbide.

In the method for manufacturing a semiconductor device of the present invention, it is preferred that the film quality alteration process is an ultraviolet irradiation process.

In the method for manufacturing a semiconductor device of the present invention, the film quality alteration process may be an electron beam irradiation process.

In the method for manufacturing a semiconductor device of the present invention, the film quality alteration process may be a heat source exposure process.

In the method for manufacturing a semiconductor device of the present invention, the film quality alteration process may be a plasma exposure process.

In such a case, it is preferred that the plasma exposure process uses a mixed gas containing one or more of ammonium, nitrogen, oxygen, helium, argon and hydrogen.

In the method for manufacturing a semiconductor device of the present invention, the film quality alteration process may be an ion implantation process.

In such a case, it is preferred that the implantation process uses a mixed gas containing one or more of silane, ammonium, nitrogen, oxygen, helium, argon, hydrogen, nitride trifluoride and carbon tetrafluoride.

In the method for manufacturing a semiconductor device of the present invention, it is preferred that the curing process is an ultraviolet irradiation process.

In the method for manufacturing a semiconductor device of the present invention, the curing process may be an electron beam irradiation process.

In the method for manufacturing a semiconductor device of the present invention, the curing process may be a heat source exposure process.

As described above, with a method for manufacturing a semiconductor device of the present invention, it is possible to prevent an increase in the tensile component of the film stress of the liner film, which is formed under the low-dielectric-constant film and over a conductor due to a curing process for an insulating film which is the low-dielectric-constant film. Thus, it is possible to prevent the interfacial peeling due to a decrease in the adhesion at the interface between the liner film and the underlying film, and it is therefore possible to obtain a semiconductor device with a high reliability having a conductor structure of a high production yield.

### BRIEF DESCRIPTION OF THE DRAWINGS

FIG. 1 is a cross-sectional view showing a semiconductor device according to a first example embodiment.

FIGS. 2A-2D are cross-sectional views showing, step by step, a method for manufacturing a semiconductor device according to the first example embodiment.

FIGS. 3A-3C are cross-sectional views showing, step by step, the method for manufacturing a semiconductor device according to the first example embodiment.

FIG. 4 is a graph showing the amount of tensile shift of the film stress in a second insulating film of the semiconductor device according to the first example embodiment, for a case where a film quality alteration process is performed and for a case where it is not performed.

FIG. 5 is a cross-sectional view showing a characteristic of a portion around a conductor of the semiconductor device according to the first example embodiment.

FIG. 6 is a cross-sectional view showing a semiconductor device according to a second example embodiment.

FIGS. 7A and 7B are cross-sectional views showing, step by step, a method for manufacturing a semiconductor device according to the second example embodiment.

FIGS. 8A-8D show a distribution in the depth direction of the chemical bond quantity ratio after a film quality alteration process for a case where a nitrogen-containing silicon carbide (SiCN) film is used as a second insulating film in the semiconductor device according to the second example embodiment. FIGS. 8A and 8B show the ratio of the silicon atom-hydrogen atom bond (Si—H) quantity with respect to the silicon atom-carbon atom bond (Si—C) quantity, wherein FIG. 8A is a graph for a case where a film quality alteration process is not performed, and FIG. 8B is a graph for a case where a film quality alteration process is performed. FIGS. 8C and 8D show the ratio of the silicon atom-methyl group (Si—CH₃) quantity with respect to the Si—C quantity, wherein FIG. 8C is a graph for a case where a film quality alteration process is not performed, and FIG. 8D is a graph for a case where a film quality alteration process is performed.

FIGS. 9A-9D show a distribution in the depth direction of the chemical bond quantity ratio after a film quality alteration process for a case where an oxygen-containing silicon carbide (SiCO) film is used as the second insulating film in the semiconductor device according to the second example embodiment. FIGS. 9A and 9B show the ratio of the Si—H quantity with respect to the Si—C quantity, wherein FIG. 9A is a graph for a case where a film quality alteration process is not performed, and FIG. 9B is a graph for a case where a film quality alteration process is performed. FIGS. 9C and 9D show the ratio of the Si—CH₃ quantity with respect to the Si—C quantity, wherein FIG. 9C is a graph for a case where a film quality alteration process is not performed, and FIG. 9D is a graph for a case where a film quality alteration process is performed.

FIGS. 10A-10D show a distribution in the depth direction of the chemical bond quantity ratio after a film quality alteration process for a case where an SiCO film is used as the second insulating film in the semiconductor device according to the second example embodiment. FIGS. 10A and 10B show the ratio of the silicon atom-oxygen atom bond (Si—O) quantity with respect to the Si—C quantity, wherein FIG. 10A is a graph for a case where a film quality alteration process is not performed, and FIG. 10B is a graph for a case where a film quality alteration process is performed. FIGS. 10C and 10D show the ratio of the Si—H quantity with respect to the Si—O quantity, wherein FIG. 10C is a graph for a case where a film quality alteration process is not performed, and FIG. 10D is a graph for a case where a film quality alteration process is performed.

### DETAILED DESCRIPTION

### First Example Embodiment

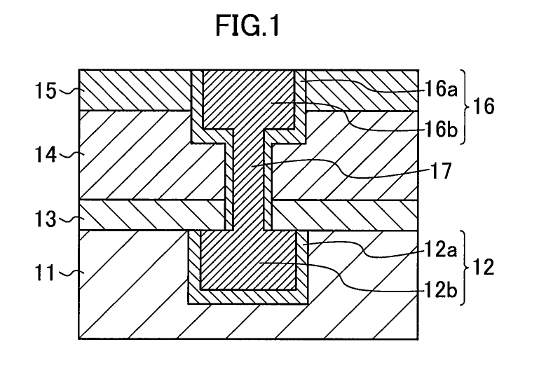

A semiconductor device according to a first example embodiment will be described with reference to FIG. 1.

As shown in FIG. 1, a first insulating film 11 made of carbon-containing silicon carbide (SiOC) is formed on or above a substrate made of silicon (Si) (not shown). A first conductor groove is formed in an upper portion of the first insulating film 11, and a first barrier metal 12a made of tantalum nitride (TaN) is formed on the bottom surface and the side wall of the first conductor groove. A first conductive film 12b made of copper (Cu) is formed on the first barrier metal 12a so as to fill up the first conductor groove, thus forming a first metal conductor 12. A second insulating film 13 which is a liner film functioning as an etch-stop film and a metal diffusion preventing film is formed on the first insulating film 11 so as to cover the first metal conductor 12.

The second insulating film 13 is made of nitrogen-containing silicon carbide (SiCN) whose dielectric constant is 6 or less. In the SiCN film which is the second insulating film 13, the ratio of the silicon-hydrogen chemical bond (Si—H) quantity with respect to the silicon-carbon chemical bond (Si—C) quantity, as determined by the Fourier transform infrared spectroscopy (FT-IR method), is 2.5% or more and 3.0% or less. It is preferred that the ratio of the silicon-methyl group chemical bond (Si—CH₃) quantity with respect to the Si—C quantity is 0.2% or more and 0.4% or less. Each chemical bond quantity is calculated from an FT-IR spectrum, and is an integral value over a measured wave number range of 2025 cm⁻¹-2290 cm⁻¹ for Si—H, over a measured wave number range of 520 cm⁻¹-1220 cm⁻¹ for Si—C, and over a measured wave number range of 1220 cm⁻¹-1280 cm⁻¹ for Si—CH₃. Each chemical bond quantity ratio is a ratio calculated from integral values of the relevant chemical bond components.

The second insulating film 13 may be oxygen-containing silicon carbide (SiCO) whose dielectric constant is 5 or less. Where an SiCO film is used as the second insulating film 13, the ratio of the Si—H quantity with respect to the Si—C quantity, as determined by the FT-IR method, is 10.0% or more and 12.0% or less. It is preferred that the ratio of the Si—CH₃ quantity with respect to the Si—C quantity is 1.0% or more and 1.8% or less. It is preferred that the ratio of the silicon-oxygen chemical bond (Si—O) quantity with respect to the Si—C quantity is 49.0% or more and 56.0% or less. It is preferred that the ratio of the Si—H quantity with respect to the Si—O quantity is 19.0% or more and 24.0% or less. Each chemical bond quantity is calculated from an FT-IR spectrum, and is an integral value over a measured wave number range of 2025 cm⁻¹-2290 cm⁻¹ for Si—H, over a measured wave number range of 600 cm⁻¹-900 cm⁻¹ for Si—C, over a measured wave number range of 1220 cm⁻¹-1280 cm⁻¹ for Si—CH₃, and over a measured wave number range of 900 cm⁻¹-1220 cm⁻¹ for Si—O. Each chemical bond quantity ratio is a ratio calculated from integral values of the relevant chemical bond components.

The second insulating film 13 may be a film having a layered structure of SiCN whose dielectric constant is 6 or less and SiCO whose dielectric constant is 5 or less.

A third insulating film 14 and a fourth insulating film 15 are formed in this order on the second insulating film 13. A second conductor groove is formed in the fourth insulating film 15 and in an upper portion of the third insulating film 14, and a via hole is formed under the second conductor groove, running through the third insulating film 14 and the second insulating film 13 and exposing the first metal conductor 12. A second barrier metal 16a made of TaN is formed on the bottom surface and the side wall of the second conductor groove and on the side wall of the via hole. A second conductive film 16b made of Cu is formed on the second barrier metal 16a so as to fill up the second conductor groove and the via hole, thus forming a second metal conductor 16 and a via 17. The first metal conductor 12 and the second metal conductor 16 are electrically connected to each other via the via 17 running through the second insulating film 13 and the third insulating film 14.

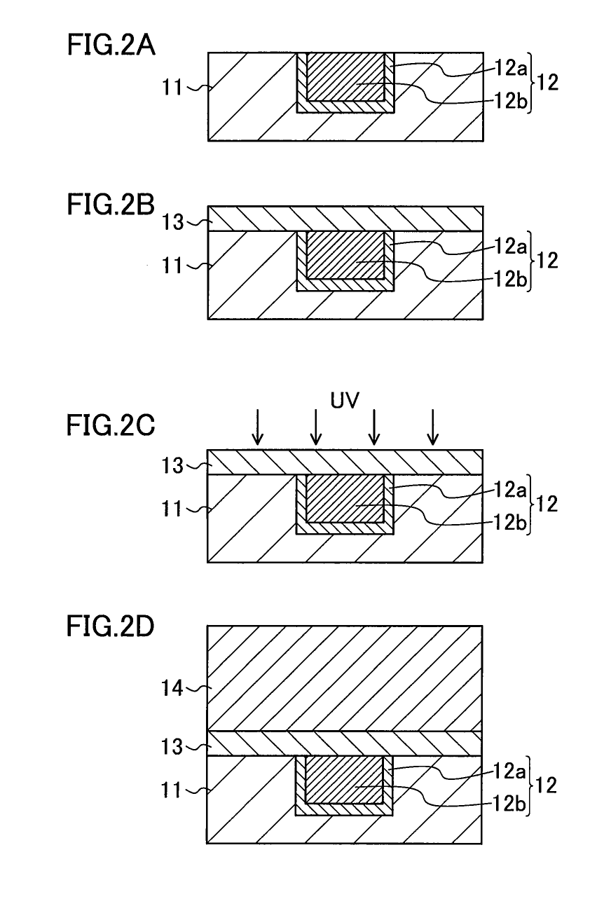

Next, a method for manufacturing a semiconductor device according to the first example embodiment will be described with reference to FIGS. 2-5.

First, as shown in FIG. 2A, the first insulating film 11 made of SiOC is formed on or above a substrate (not shown), a resist is applied on the first insulating film 11, and a first conductor groove pattern is formed by using a photolithography method. Then, a first conductor groove is formed in an upper portion of the first insulating film 11 by a dry etching method using the formed pattern as a mask, and the resist is removed by an ashing method. Then, the first barrier metal 12a made of TaN is formed by a sputtering method on the bottom surface and the side wall of the first conductor groove and on the first insulating film, and the first conductive film 12b made of Cu is formed by an electroplating method on the first barrier metal 12a so as to fill up the first conductor groove. Then, an excess of the first barrier metal 12a and the first conductive film 12b on the first insulating film 11 outside the first conductor groove is removed by a chemical mechanical polishing (CMP) method, thus forming the first metal conductor 12 including the first barrier metal 12a and the first conductive film 12b.

Then, as shown in FIG. 2B, the second insulating film 13 made of SiCN whose dielectric constant is 6 or less and whose thickness is 20 nm is formed by a chemical vapor deposition (CVD) method using organosilane and ammonium (NH₃) as source materials on the first insulating film 11 so as to cover the first metal conductor 12. Here, the second insulating film 13 is an SiCN film formed by a CVD method, for example, under such conditions that the deposition temperature is 370° C., the flow rate of tetramethylsilane is 440 ml/min (0° C., 1 atm), the flow rate of NH₃ is 500 ml/min (0° C., 1 atm), the flow rate of helium (He) is 5000 ml/min (0° C., 1 atm), the deposition pressure is 665 Pa, and the RF power is 1000 W (higher frequency: 27.1 MHz) and 210 W (lower frequency: 13.56 MHz). The second insulating film 13 may be a film made of SiCO whose dielectric constant is 5 or less formed by a CVD method using organosilane and carbon dioxide (CO₂) as source materials. The second insulating film 13 is an SiCO film formed by a CVD method, for example, under such conditions that the deposition temperature is 370° C., the flow rate of tetramethylsilane is 450 ml/min (0° C., 1 atm), the flow rate of CO₂ is 2850 ml/min (0° C., 1 atm), the flow rate of He is 3000 ml/min (0° C., 1 atm), the deposition pressure is 530 Pa, and the RF power is 830 W (higher frequency: 27.1 MHz) and 230 W (lower frequency: 13.56 MHz). The second insulating film 13 may be a layered film of an SiCN film whose dielectric constant is 6 or less formed by a CVD method using organosilane and NH₃ as source materials, and an SiCO film whose dielectric constant is 5 or less formed by a CVD method using organosilane and CO₂ as source materials.

Then, as shown in FIG. 2C, the second insulating film 13 is subjected to a film quality alteration process by ultraviolet (UV) irradiation. Conditions, etc., of the UV irradiation will be described later.

Then, as shown in FIG. 2D, the third insulating film 14 made of SiOC whose dielectric constant is 3 or less and whose thickness is 125 nm is formed by a CVD method on the second insulating film 13, and a UV curing process for the third insulating film 14 is performed. Conditions, etc., of the UV irradiation will be described later.

Typically, since curing light (UV light) used in a UV curing process passes through to a layer underlying the cured layer, an insulating film underlying the cured layer is likely to be damaged by the UV light during the UV curing process. Specifically, an excess of the curing energy passing through the cured layer impinges upon the underlying insulating film, forming a defect in the underlying insulating film. In order to prevent this, a curing light blocking layer (UV blocking film) is provided under the cured layer to block the UV light so that the insulating film is not influenced by the UV light. However, while this method can reduce the influence of the UV light on any film below the UV blocking film, it does not address the UV light absorption by the UV blocking film itself, thus failing to reduce defects in the UV blocking film. In view of this, in the present embodiment, the second insulating film 13 is subjected to a film quality alteration process described above so that it does not absorb an excess of UV light passing through the cured layer. Thus, it is possible to reduce the problematic absorption by the second insulating film 13 of the UV light passing through the third insulating film 14 to reach the underlying layer, and it is possible to prevent a film damage on the underlying second insulating film 13 during the UV curing process for the third insulating film 14.

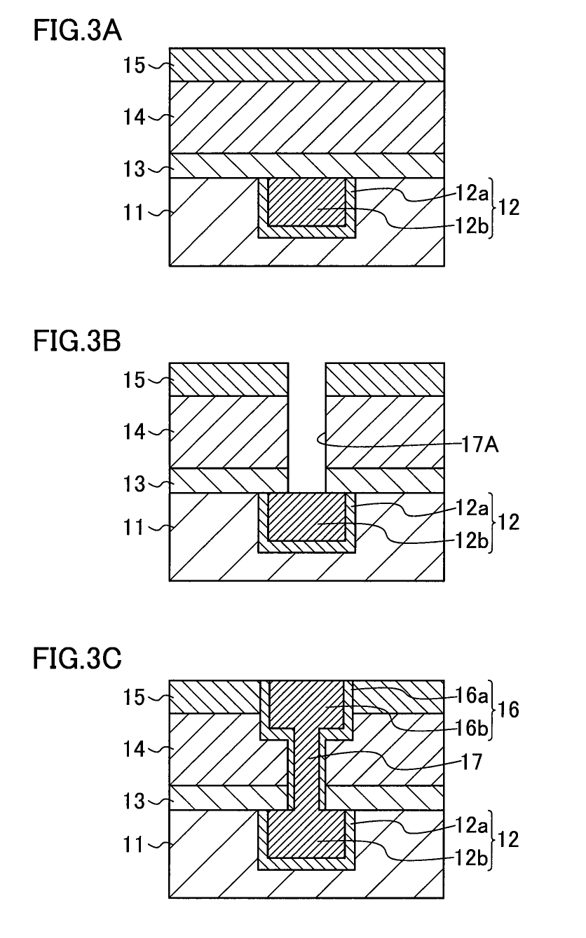

Then, as shown in FIG. 3A, the fourth insulating film 15 whose thickness is 80 nm is formed on the third insulating film 14, a resist (not shown) is applied on the surface of the fourth insulating film 15, and a via hole pattern is formed by using a photolithography method.

Then, as shown in FIG. 3B, dry etching is performed using the formed pattern as a mask so as to form a via hole 17A running through the second insulating film 13, the third insulating film 14 and the fourth insulating film 15 and exposing the first metal conductor 12. Then, the resist is removed by ashing.

Then, as shown in FIG. 3C, a resist (not shown) is applied again on the fourth insulating film 15, and a second conductor groove pattern is formed by using a photolithography method. Then, dry etching is performed using the pattern as a mask so as to form a second conductor groove in an upper portion of the third insulating film 14 and the fourth insulating film 15. Then, the resist is removed by ashing. Then, the second barrier metal 16a made of TaN is formed on the bottom surface and the side wall of the second conductor groove, the side wall of the via hole 17A and the fourth insulating film 15 by a sputtering method. Then, the second conductive film 16b made of Cu is formed by an electroplating method on the second barrier metal 16a so as to fill up the via hole 17A and the second conductor groove. Then, an excess of the second barrier metal 16a and the second conductive film 16b on the fourth insulating film 15 outside the second conductor groove is removed by a CMP method, thus forming the second metal conductor 16 and the via 17 including the second barrier metal 16a and the second conductive film 16b.

Conditions of the UV irradiation for the second insulating film 13 will now be described.

The UV irradiation is performed in an He or nitrogen (N₂) atmosphere or an atmosphere containing He or N₂ and at least one other element under such conditions that the temperature is 300° C.-500° C., the pressure is 10⁻⁸ Pa-1.013×10⁵ Pa (=1 atm), the UV intensity is 30 mW/cm²-500 mW/cm², the UV irradiation power is 30 W-500 W, and the UV irradiation time is 30 s-1200 s. While a UV irradiation process is performed as a film quality alteration process for the second insulating film 13 in the present embodiment, the present invention is not limited to this.

First, the second insulating film 13 may be irradiated with an electron beam. The electron beam irradiation is performed in an He atmosphere under such conditions that the temperature is 300° C.-500° C., the pressure is 10⁻⁸ Pa-10⁴ Pa, the electron beam power is 10 kW-100 kW, and the electron beam irradiation time is 30 s-500 s.

Second, the second insulating film 13 may be exposed to a heat source. The heat exposure is performed in an He, N₂ or hydrogen (H₂) atmosphere under such conditions that the temperature is 100° C.-1200° C., the pressure is 10⁻⁴ Pa-1.013×10⁵ Pa (=1 atm), and the exposure time is 10 min-120 min.

Third, the second insulating film 13 may be exposed to a plasma. The plasma exposure is performed in an atmosphere containing one or more of NH₃, N₂, oxygen (O₂), He, argon (Ar) and H₂ under such conditions that the temperature is 300° C.-500° C., the pressure is 10⁻⁸ Pa-1.013×10⁵ Pa (=1 atm), the RF power is 100 W-1000 W, and the plasma exposure time is 5 s-10 min.

Fourth, the second insulating film 13 may be subjected to an ion implantation process. In the implantation process, a gas containing one or more of silane (SiH₄), NH₃, N₂, O₂, He, Ar, H₂, nitride trifluoride (NF₃) and carbon tetrafluoride (CF₄) is ionized and implanted by a gas cluster ion beam method. It is performed under such conditions that the acceleration potential is 3 kV-100 kV, and the dose is 10¹⁰ ions/cm²-10¹⁸ ions/cm².

With any of the first to fourth methods above, there is an advantage described above for the second insulating film 13.

Conditions of the UV irradiation for the third insulating film 14 will now be described.

The UV irradiation is performed in an He or N₂ atmosphere or an atmosphere containing He or N₂ and at least one other element under such conditions that the temperature is 300° C.-500° C., the pressure is 10⁻⁸ Pa-1.013×10⁵ Pa (=1 atm), the UV intensity is 30 mW/cm²-500 mW/cm²′ the UV irradiation power is 30 W-500 W, and the UV irradiation time is 30 s-1200 s. While a UV irradiation process is performed as a curing process for the third insulating film 14 in the present embodiment, the present invention is not limited to this.

First, the third insulating film 14 may be irradiated with an electron beam. The electron beam irradiation is performed in an He atmosphere under such conditions that the temperature is 300° C.-500° C., the pressure is 10⁻⁸ Pa-10⁻⁴ Pa, the electron beam power is 10 kW-100 kW, and the electron beam irradiation time is 60 s-500 s.

Second, the third insulating film 14 may be exposed to a heat source. The heat exposure is performed in an He, N₂ or H₂ atmosphere under such conditions that the temperature is 100° C.-1200° C., the pressure is 10⁴ Pa-1.013×10⁵ Pa (=1 atm), and the exposure time is 10 min-120 min.

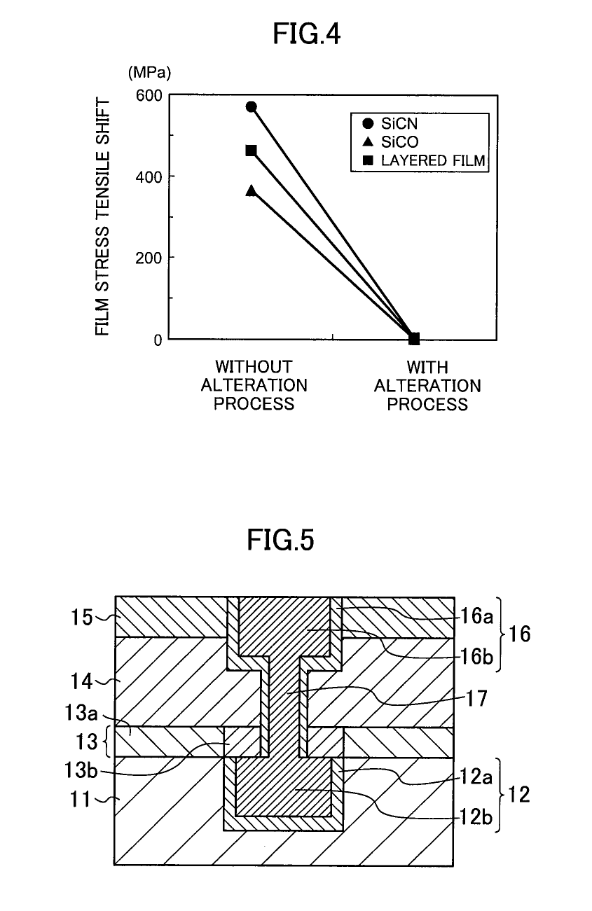

The relationship between the influence of the UV curing process for the third insulating film 14 on the second insulating film 13 and a film quality alteration process will now be described with reference to FIG. 4.

As shown in FIG. 4, it can be seen that a film quality alteration process is effective in reducing the increase in the tensile component of the film stress due to the UV curing process, whether the second insulating film 13 is an SiCN film, an SiCO film or a layered film of an SiCN film and an SiCO film. Note that a UV curing process is performed directly on the second insulating film 13 in this evaluation because it is an accelerated test.

TABLE 1 and TABLE 2 show chemical bond quantity ratios for a case where a film quality alteration process is performed for the second insulating film 13 by a method described above and for a case where it is not performed, and also show amounts of tensile shift in the film stress due to the UV curing process. TABLE 1 shows a case where an SiCN film is used as the second insulating film 13, and TABLE 2 shows a case where an SiCO film is used as the second insulating film 13.

TABLE 1

| | Without Alteration | |
|---|---|---|
| | Process | With Alteration Process |
| Film Stress Tensile | +569 | +3-+30 |
| Shift (MPa) | | |
| Si—H/Si—C (%) | 3.9 | 2.5-3.0 |
| Si—CH₃/Si—C (%) | 0.5 | 0.2-0.4 |

TABLE 2

| | Without Alteration | |
|---|---|---|
| | Process | With Alteration Process |
| Film Stress Tensile | +366 | +3-+30 |
| Shift (MPa) | | |
| Si—H/Si—C (%) | 13.0 | 10-12 |
| Si—CH₃/Si—C (%) | 2.0 | 1.0-1.8 |
| Si—O/Si—C (%) | 37.0 | 56.0-49.0 |
| Si—H/Si—O (%) | 34.5 | 19.0-24.0 |

As shown in TABLE 1, it can be seen that as compared with an SiCN film not subjected to a film quality alteration process, an SiCN film subjected to a film quality alteration process has a lower ratio of the Si—H quantity with respect to the Si—C quantity and a lower ratio of the Si—CH₃ quantity with respect to the Si—C quantity, and has a smaller amount of tensile shift in the film stress due to the UV curing process. Typically, when an SiCN film receives an excessive optical energy and thermal energy, there occurs a cleavage in Si—H and Si—CH₃ which have relatively weak binding energies. The film quality alteration process removes these unstable bonds in advance, thereby preventing these cleavage reactions due to the excessive optical energy and thermal energy passing through the third insulating film 14 to reach the second insulating film 13 during the curing process for the third insulating film 14.

As shown in TABLE 2, it can be seen that as compared with an SiCO film not subjected to a film quality alteration process, an SiCO film subjected to a film quality alteration process has a lower ratio of the Si—H quantity with respect to the Si—C quantity, a lower ratio of the Si—CH₃ quantity with respect to the Si—C quantity, a lower ratio of the Si—H quantity with respect to the Si—C quantity, a higher ratio of the Si—CH₃ quantity with respect to the Si—C quantity, and has a smaller amount of tensile shift in the film stress due to the curing process. Typically, when an SiCO film receives an excessive optical energy and thermal energy, there occurs a cleavage in Si—H and Si—CH₃ which have relatively weak binding energies, thus increasing the Si—O quantity. The film quality alteration process removes these unstable bonds in advance, thereby preventing these cleavage reactions due to the excessive optical energy and thermal energy passing through the third insulating film 14 to reach the second insulating film 13 during the curing process for the third insulating film 14.

A characteristic of a portion around a conductor of a semiconductor device formed by the method described above will be described with reference to FIG. 5.

As shown in FIG. 5, the second insulating film 13 is divided into a second insulating film 13a formed on the first insulating film 11 and a second insulating film 13b formed on the first metal conductor 12, which have different chemical bond quantity ratios.

TABLE 3 and TABLE 4 show the chemical bond quantity ratio of the second insulating film 13b on the first metal conductor and that of the second insulating film 13a on the first insulating film, specifically, the chemical bond quantity ratio between two different chemical bonds to be compared with each other of the second insulating film 13b on the first metal conductor with respect to that of the second insulating film 13a on the first insulating film being 1. TABLE 3 shows a case where an SiCN film is used as the second insulating film 13, and TABLE 4 shows a case where an SiCO film is used as the second insulating film 13.

TABLE 3

| | | On First Metal |
|---|---|---|
| | On First Insulating Film | Conductor |
| Si—H/Si—C (arb. unit) | 1.0 | 0.85-1.0 |
| Si—CH₃/Si—C (arb. unit) | 1.0 | 0.55-1.0 |

TABLE 4

| | | On First Metal |
|---|---|---|
| | On First Insulating Film | Conductor |
| Si—H/Si—C (arb. unit) | 1.0 | 0.95-1.0 |
| Si—CH₃/Si—C (arb. unit) | 1.0 | 0.45-1.0 |
| Si—O/Si—C (arb. unit) | 1.0 | 1.0-1.1 |
| Si—H/Si—O (arb. unit) | 1.0 | 0.8-1.0 |

As shown in TABLE 3, the chemical bond quantity ratio Si—H/Si—C is 0.85 or more and 1.0 or less in the second insulating film 13b on the first metal conductor when that in the second insulating film 13a on the first insulating film is assumed to be 1.0. The chemical bond quantity ratio Si—CH₃/Si—O is 0.55 or more and 1.0 or less in the second insulating film 13b on the first metal conductor 12 when that in the second insulating film 13a on the first insulating film is assumed to be 1.0. Since the chemical bond quantity ratios are both lower in the second insulating film 13b on the first metal conductor, it is believed that the second insulating film 13b on the first metal conductor receives more curing energy than the second insulating film 13a on the first insulating film. The reason is that the optical energy and the thermal energy having passed through the SiCN film during the curing process for the third insulating film 14 are reflected at the upper surface of the first metal conductor 12 to act again upon the SiCN film.

As shown in TABLE 4, the chemical bond quantity ratio Si—H/Si—C is 0.95 or more and 1.0 or less in the second insulating film 13b on the first metal conductor 12 when that in the second insulating film 13a on the first insulating film is assumed to be 1.0. The chemical bond quantity ratio Si—CH₃/Si—O is 0.45 or more and 1.0 or less in the second insulating film 13b on the first metal conductor 12 when that in the second insulating film 13a on the first insulating film is assumed to be 1.0. The chemical bond quantity ratio Si—O/Si—C is 1.0 or more and 1.1 or less in the second insulating film 13b on the first metal conductor 12 when that in the second insulating film 13a on the first insulating film 11 is assumed to be 1.0. The chemical bond quantity ratio Si—H/Si-0 is 0.8 or more and 1.0 or less in the second insulating film 13b on the first metal conductor when that in the second insulating film 13a on the first insulating film is assumed to be 1.0. Since the chemical bond quantity ratios Si—H/Si—C, Si—CH₃/Si—O and Si—H/Si—O are lower in the second insulating film 13b on the first metal conductor and the chemical bond quantity ratio Si—O/Si—C is higher in the second insulating film 13b on the first metal conductor, it is believed that more curing energy is received on the first metal conductor than on the first insulating film. The reason is that the optical energy and the thermal energy having passed through the SiCO film during the curing process for the third insulating film are reflected at the upper surface of the first metal conductor 12 to act again upon the SiCO film.

With the method for manufacturing a semiconductor device according to the first example embodiment, it is possible to prevent an increase in the tensile component of the film stress of the second insulating film due to the curing process for the third insulating film, and it is therefore possible to prevent the interfacial peeling between the second insulating film and the underlying film due to a decrease in the adhesion at the interface therebetween. As a result, it is possible to obtain a semiconductor device with a high reliability having a conductor structure of a high production yield.

### Second Example Embodiment

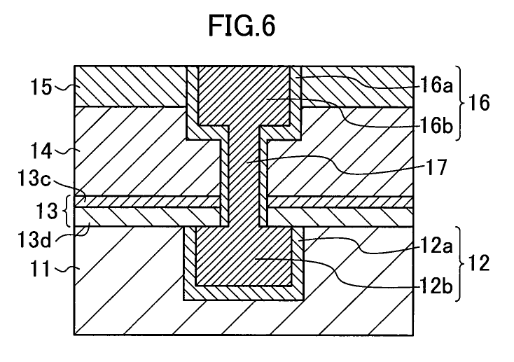

A semiconductor device according to a second example embodiment will be described with reference to FIG. 6. In the second example embodiment, like elements to those of the first example embodiment will be denoted by like reference characters and will not be described below.

As shown in FIG. 6, the second insulating film 13 which is a liner film functioning as an etch-stop film and a metal diffusion preventing film is formed on the first insulating film 11 so as to cover the first metal conductor 12.

The second insulating film 13 is made of SiCN whose dielectric constant is 6 or less. In the SiCN film which is the second insulating film 13, the ratio of the Si—H quantity with respect to the Si—C quantity, as determined by the FT-IR method, is lower in an upper portion 13c of the second insulating film (a portion on the side of the surface in contact with the third insulating film 14) than in a lower portion 13d of the second insulating film (a portion on the side of the surface in contact with the first insulating film 11). The rate of change of the chemical bond quantity ratio ((the chemical bond quantity ratio in the lower portion 13d of the second insulating film—the chemical bond quantity ratio in the upper portion 13c of the second insulating film)/the chemical bond quantity ratio in the lower portion 13d of the second insulating film) is 36% or less. The ratio of the Si—H quantity with respect to the Si—C quantity in an upper portion of the SiCN film which is the upper portion 13c of the second insulating film, as determined by the FT-IR method, is 2.5% or more and 3.0% or less. It is preferred that the ratio of the Si—CH₃ quantity with respect to the Si—C quantity is lower in the upper portion 13c of the second insulating film than in the lower portion 13d of the second insulating film, and the rate of change of the chemical bond quantity ratio is 39% or less. It is preferred that the ratio of the Si—CH₃ quantity with respect to the Si—C quantity in an upper portion of the SiCN film which is the upper portion 13c of the second insulating film, as determined by the FT-IR method, is 0.2%-0.4%. Each chemical bond quantity is calculated from an FT-IR spectrum, and is an integral value over a measured wave number range of 2025 cm⁻¹-2290 cm⁻¹ for Si—H, over a measured wave number range of 520 cm⁻¹-1220 cm⁻¹ for Si—C, and over a measured wave number range of 1220 cm⁻¹-1280 cm⁻¹ for Si—CH₃. Each chemical bond quantity ratio is a ratio calculated from integral values of the relevant chemical bond components.

The second insulating film 13 may be an SiCO film whose dielectric constant is 5 or less. Where an SiCO film is used as the second insulating film 13, the ratio of the Si—H quantity with respect to the Si—C quantity as determined by the FT-IR method is lower in the upper portion 13c of the second insulating film than in the lower portion 13d of the second insulating film. The rate of change of the chemical bond quantity ratio is 14% or less. The ratio of the Si—H quantity with respect to the Si—C quantity in an upper portion of the SiCO film which is the upper portion 13c of the second insulating film, as determined by the FT-IR method, is 10.0% or more and 12.0% or less. It is preferred that the ratio of the Si—CH₃ quantity with respect to the Si—C quantity is lower in the upper portion 13c of the second insulating film than in the lower portion 13d of the second insulating film, and the rate of change of the chemical bond quantity ratio is 41% or less. It is preferred that the ratio of the Si—CH₃ quantity with respect to the Si—C quantity in an upper portion of the SiCO film which is the upper portion 13c of the second insulating film, as determined by the FT-IR method, is 1.0% or more and 2.0% or less. It is preferred that the ratio of the Si—O quantity with respect to the Si—C quantity is higher in the upper portion 13c of the second insulating film than in the lower portion 13d of the second insulating film, and the rate of change of the chemical bond quantity ratio is 52% or less. It is preferred that the ratio of the Si—O quantity with respect to the Si—C quantity in an upper portion of the SiCO film which is the upper portion 13c of the second insulating film, as determined by the FT-IR method, is 49.0% or more and 56.0% or less. It is preferred that the ratio of the Si—H quantity with respect to the Si—O quantity is lower in the upper portion 13c of the second insulating film than in the lower portion 13d of the second insulating film, and the rate of change of the chemical bond quantity ratio is 44% or less. It is preferred that the ratio of the Si—H quantity with respect to the Si—O quantity in an upper portion of the SiCO film which is the upper portion 13c of the second insulating film, as determined by the FT-IR method, is 19.0% or more and 24.0% or less. Each chemical bond quantity is calculated from an FT-IR spectrum, and is an integral value over a measured wave number range of 2025 cm⁻¹-2290 cm⁻¹ for Si—H, over a measured wave number range of 600 cm⁻¹-900 cm⁻¹ for Si—C, over a measured wave number range of 1220 cm⁻¹-1280 cm⁻¹ for Si—CH₃, and over a measured wave number range of 900 cm⁻¹-1220 cm⁻¹ for Si—O. Each chemical bond quantity ratio is a ratio calculated from integral values of the relevant chemical bond components.

The second insulating film 13 may be a film having a layered structure of SiCN whose dielectric constant is 6 or less and SiCO whose dielectric constant is 5 or less.

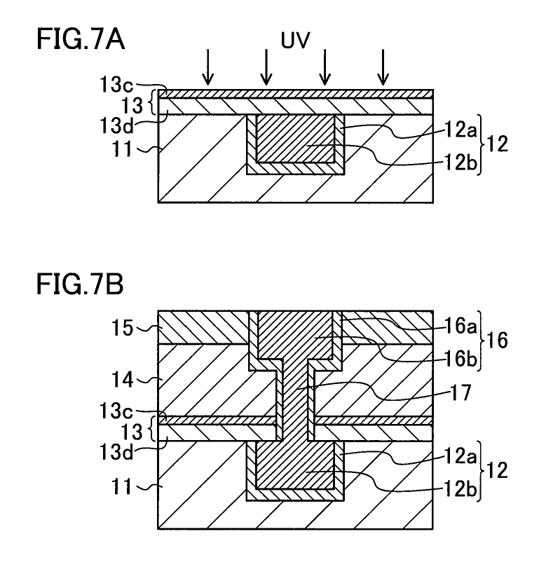

Next, a method for manufacturing a semiconductor device according to the second example embodiment will be described with reference to FIGS. 7-10. In the second example embodiment, like elements to those of the first example embodiment will be denoted by like reference characters and will not be described below, and like steps will also not be described below, describing only the differences.

As shown in FIG. 7A, the second insulating film 13 made of SiCN whose dielectric constant is 6 or less and whose thickness is 20 nm is formed by a CVD method using organosilane and NH₃ as source materials on the first insulating film 11 so as to cover the first metal conductor 12. Here, the second insulating film 13 is an SiCN film formed by a CVD method, for example, under such conditions that the deposition temperature is 370° C., the flow rate of tetramethylsilane is 440 ml/min (0° C., 1 atm), the flow rate of NH₃ is 500 ml/min (0° C., 1 atm), the flow rate of He is 5000 ml/min (0° C., 1 atm), the deposition pressure is 665 Pa, and the RF power is 1000 W (higher frequency: 27.1 MHz) and 210 W (lower frequency: 13.56 MHz). The second insulating film 13 may be a film made of SiCO whose dielectric constant is 5 or less formed by a CVD method using organosilane and CO₂ as source materials. For example, it is an SiCO film formed by a CVD method under such conditions that the deposition temperature is 370° C., the flow rate of tetramethylsilane is 450 ml/min (0° C., 1 atm), the flow rate of CO₂ is 2850 ml/min (0° C., 1 atm), the flow rate of He is 3000 ml/min (0° C., 1 atm), the deposition pressure is 530 Pa, and the RF power is 830 W (higher frequency: 27.1 MHz) and 230 W (lower frequency: 13.56 MHz). The second insulating film 13 may be a layered film of an SiCN film whose dielectric constant is 6 or less formed by a CVD method using organosilane and NH₃ as source materials, and an SiCO film whose dielectric constant is 5 or less formed by a CVD method using organosilane and CO₂ as source materials. Then, the second insulating film 13 is subjected to a UV irradiation process. Conditions, etc., of the UV irradiation will be described later.

Then, as shown in FIG. 7B, the third insulating film 14 and the fourth insulating film 15 are formed as described above in the first example embodiment, thus forming the second metal conductor 16 and the via 17 including the second barrier metal 16a and the second conductive film 16b.

Conditions of the UV irradiation for the second insulating film 13 will now be described.

The UV irradiation is performed in an atmosphere containing He or N₂ or an atmosphere containing He or N₂ and at least one other element under such conditions that the temperature is 300° C.-500° C., the pressure is 10⁻⁸ Pa-1.013×10⁵ Pa (=1 atm), the UV intensity is 30 mW/cm²-500 mW/cm², the UV irradiation power is 30 W-500 W, and the UV irradiation time is 15 s-600 s. While a UV irradiation process is performed as a film quality alteration process for the second insulating film 13 in the present embodiment, the present invention is not limited to this.

First, the second insulating film 13 may be irradiated with an electron beam. The electron beam irradiation is performed in an He atmosphere under such conditions that the temperature is 300° C.-500° C., the pressure is 10⁻⁸ Pa-10⁻⁴ Pa, the electron beam power is 10 kW-100 kW, and the electron beam irradiation time is 30 s-250 s.

Second, the second insulating film 13 may be exposed to a heat source. The heat exposure is performed in an He, N₂ or H₂ atmosphere under such conditions that the temperature is 100° C.-1200° C., the pressure is 10⁻⁴ Pa-1.013×10⁵ Pa (=1 atm), and the exposure time is 10 min-60 min.

Third, the second insulating film 13 may be exposed to a plasma. The plasma exposure is performed in an atmosphere containing one or more of NH₃, N₂, O₂, He, Ar and H₂ under such conditions that the temperature is 300° C.-500° C., the pressure is 10⁻⁸ Pa-1.013×10⁵ Pa (=1 atm), the RF power is 100 W-1000 W, and the exposure time is 5 s-5 min.

Fourth, the second insulating film 13 may be subjected to an implantation process. In the implantation process, a gas containing one or more of SiH₄, NH₃, N₂, O₂, He, Ar, H₂, NF₃ and CF₄ is ionized and implanted by a gas cluster ion beam method. It is performed under such conditions that the acceleration potential is 3 kV-100 kV, and the dose is 10¹⁰ ions/cm²-10¹⁷ ions/cm².

With any of the first to fourth methods above, there is an advantage described above for the second insulating film 13.

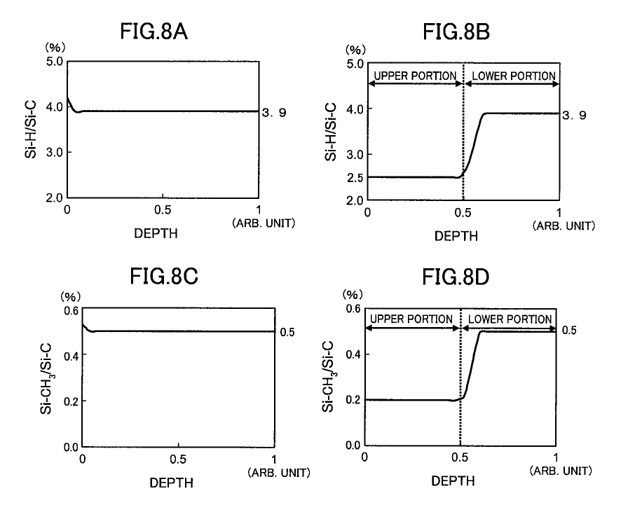

The relationship between the physical property of the second insulating film 13 and a film quality alteration process will now be described with reference to FIGS. 8-10.

As shown in FIGS. 8A-8D, it can be seen that the ratio of the Si—H quantity with respect to the Si—C quantity and the ratio of the Si—CH₃ quantity with respect to the Si—C quantity are lower in an upper portion of an SiCN film which is the second insulating film 13 subjected to a film quality alteration process, as compared with a case where the film quality alteration process is not performed. Typically, when an SiCN film receives an excessive optical energy and thermal energy, there occurs a cleavage in Si—H and Si—CH₃ which have relatively weak binding energies. The film quality alteration process removes these unstable bonds in a film upper portion in advance, thereby preventing these cleavage reactions due to the excessive optical energy and thermal energy passing through the third insulating film 14 to reach the second insulating film 13 during the curing process for the third insulating film 14.

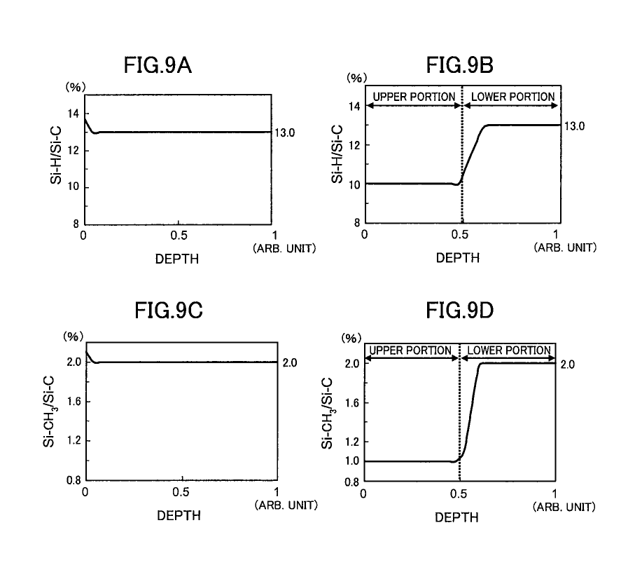

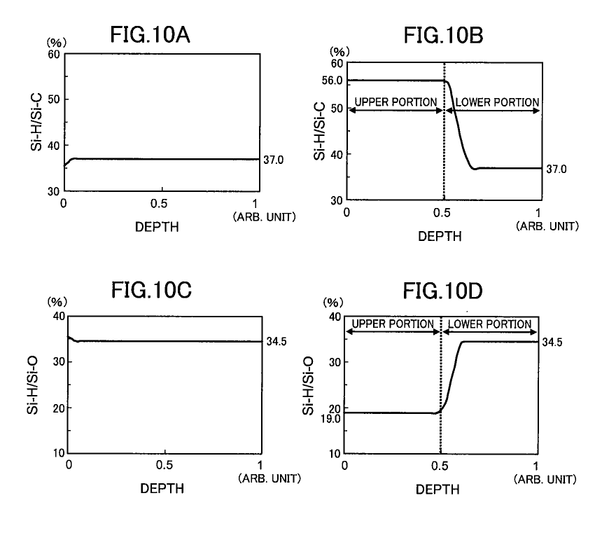

As shown in FIGS. 9A-9D and 10A-10D, it can be seen that where an SiCO film is used as the second insulating film 13, the ratio of the Si—H quantity with respect to the Si—C quantity, the ratio of the Si—CH₃ quantity with respect to the Si—C quantity and the ratio of the Si—H quantity with respect to the Si—C quantity are lower and the ratio of the Si—CH₃ quantity with respect to the Si—C quantity is higher in an upper portion of the SiCO film subjected to a film quality alteration process, as compared with a case where the alteration process is not performed. Typically, when an SiCO film receives an excessive optical energy and thermal energy, there occurs a cleavage in Si—H and Si—CH₃ which have relatively weak binding energies, thus increasing Si—O. The film quality alteration process removes these unstable bonds in a film upper portion in advance, thereby preventing these cleavage reactions due to the excessive optical energy and thermal energy passing through the third insulating film 14 to reach the second insulating film 13 during the curing process for the third insulating film 14.

With the method for manufacturing a semiconductor device according to the second example embodiment, it is possible to prevent an increase in the tensile component of the film stress of the second insulating film due to the curing process for the third insulating film, and it is therefore possible to prevent the interfacial peeling between the second insulating film and the underlying film due to a decrease in the adhesion at the interface therebetween. As a result, it is possible to obtain a semiconductor device with a high reliability having a conductor structure of a high production yield.

As described above, the method for manufacturing a semiconductor device according to the present disclosure provides a semiconductor device with a high reliability having a conductor structure of a high production yield, and is useful as, for example, a method for manufacturing a semiconductor device including a metal conductor made of copper, or the like, and an inter-layer dielectric having a low dielectric constant.

What is claimed is:

1. A method for manufacturing a semiconductor device, the method comprising the steps of:
(a) forming a first insulating film on or above a substrate, and forming a first conductor in an upper portion of the formed first insulating film;
(b) forming a second insulating film on the first insulating film so as to cover the first conductor;
(c) performing a film quality alteration process for the second insulating film; and
(d) forming a third insulating film on the second insulating film, and performing a curing process for the formed third insulating film, after the step (c).

2. The method for manufacturing a semiconductor device of claim 1, wherein
the second insulating film is made of nitrogen-containing silicon carbide.

3. The method for manufacturing a semiconductor device of claim 2, wherein
a ratio of a silicon atom-hydrogen atom chemical bond quantity with respect to a silicon atom-carbon atom chemical bond quantity in the second insulating film is 2.5% or more and 3.0% or less.

4. The method for manufacturing a semiconductor device of claim 3, wherein
a ratio of a silicon atom-methyl group chemical bond quantity with respect to a silicon atom-carbon atom chemical bond quantity in the second insulating film is 0.2% or more and 0.4% or less.

5. The method for manufacturing a semiconductor device of claim 2, wherein
a ratio of a silicon atom-hydrogen atom chemical bond quantity with respect to a silicon atom-carbon atom chemical bond quantity in an upper portion of the second insulating film is lower than that in a lower portion of the second insulating film, and a rate of change therebetween is 36% or less.

6. The method for manufacturing a semiconductor device of claim 2, wherein
a ratio of a silicon atom-methyl group chemical bond quantity with respect to a silicon atom-carbon atom chemical bond quantity in an upper portion of the second insulating film is lower than that in a lower portion of the second insulating film, and a rate of change therebetween is 39% or less.

7. The method for manufacturing a semiconductor device of claim 2, wherein
a ratio of a silicon atom-hydrogen atom chemical bond quantity with respect to a silicon atom-carbon atom chemical bond quantity in a portion of the second insulating film on the first conductor is lower than or equal to that in a portion of the second insulating film on the first insulating film, and a ratio therebetween is 0.85 or more and 1.00 or less.

8. The method for manufacturing a semiconductor device of claim 2, wherein
a ratio of a silicon atom-methyl group chemical bond quantity with respect to a silicon atom-carbon atom chemical bond quantity in a portion of the second insulating film on the first conductor is less than or equal to that in a portion of the second insulating film on the first insulating film, and a ratio therebetween is 0.55 or more and 1.00 or less.

9. The method for manufacturing a semiconductor device of claim 1, wherein
the second insulating film is made of oxygen-containing silicon carbide.

10. The method for manufacturing a semiconductor device of claim 9, wherein
a ratio of a silicon atom-hydrogen atom chemical bond quantity with respect to a silicon atom-carbon atom chemical bond quantity in the second insulating film is 10.0% or more and 12.0% or less.

11. The method for manufacturing a semiconductor device of claim 10, wherein
a ratio of a silicon atom-methyl group chemical bond quantity with respect to a silicon atom-carbon atom chemical bond quantity in the second insulating film is 1.0% or more and 1.8% or less.

12. The method for manufacturing a semiconductor device of claim 10, wherein
a ratio of a silicon atom-oxygen atom chemical bond quantity with respect to a silicon atom-carbon atom chemical bond quantity in the second insulating film is 49.0% or more and 56.0% or less.

13. The method for manufacturing a semiconductor device of claim 10, wherein
a ratio of a silicon atom-hydrogen atom chemical bond quantity with respect to a silicon atom-oxygen atom chemical bond quantity in the second insulating film is 19.0% or more and 24.0% or less.

14. The method for manufacturing a semiconductor device of claim 9, wherein
a ratio of a silicon atom-hydrogen atom chemical bond quantity with respect to a silicon atom-carbon atom chemical bond quantity in an upper portion of the second insulating film is lower than that in a lower portion of the second insulating film, and a rate of change therebetween is 14% or less.

15. The method for manufacturing a semiconductor device of claim 9, wherein
a ratio of a silicon atom-methyl group chemical bond quantity with respect to a silicon atom-carbon atom chemical bond quantity in an upper portion of the second insulating film is lower than that in a lower portion of the second insulating film, and a rate of change therebetween is 41% or less.

16. The method for manufacturing a semiconductor device of claim 9, wherein
a ratio of a silicon atom-oxygen atom chemical bond quantity with respect to a silicon atom-carbon atom chemical bond quantity in an upper portion of the second insulating film is higher than that in a lower portion of the second insulating film, and a rate of change therebetween is 52% or less.

17. The method for manufacturing a semiconductor device of claim 9, wherein
a ratio of a silicon atom-hydrogen atom chemical bond quantity with respect to a silicon atom-oxygen atom chemical bond quantity in an upper portion of the second insulating film is lower than that in a lower portion of the second insulating film, and a rate of change therebetween is 44% or less.

18. The method for manufacturing a semiconductor device of claim 9, wherein
a ratio of a silicon atom-hydrogen atom chemical bond quantity with respect to a silicon atom-carbon atom chemical bond quantity in a portion of the second insulating film on the first conductor is less than or equal to that in a portion of the second insulating film on the first insulating film, and a ratio therebetween is 0.95 or more and 1.00 or less.

19. The method for manufacturing a semiconductor device of claim 9, wherein
a ratio of a silicon atom-methyl group chemical bond quantity with respect to a silicon atom-carbon atom chemical bond quantity in a portion of the second insulating film on the first conductor is less than or equal to that in a portion of the second insulating film on the first insulating film, and a ratio therebetween is 0.45 or more and 1.00 or less.

20. The method for manufacturing a semiconductor device of claim 9, wherein
a ratio of a silicon atom-oxygen atom chemical bond quantity with respect to a silicon atom-carbon atom chemical bond quantity in a portion of the second insulating film on the first conductor is greater than or equal to that in a portion of the second insulating film on the first insulating film, and a ratio therebetween is 1.00 or more and 1.10 or less.

21. The method for manufacturing a semiconductor device of claim 9, wherein
a ratio of a silicon atom-hydrogen atom chemical bond quantity with respect to a silicon atom-oxygen atom chemical bond quantity in a portion of the second insulating film on the first conductor is less than or equal to that in a portion of the second insulating film on the first insulating film, and a ratio therebetween is 0.80 or more and 1.00 or less.

22. The method for manufacturing a semiconductor device of claim 1, wherein
the second insulating film has a layered structure of nitrogen-containing silicon carbide and oxygen-containing silicon carbide.

23. The method for manufacturing a semiconductor device of claim 1, wherein
the film quality alteration process is an ultraviolet irradiation process.

24. The method for manufacturing a semiconductor device of claim 1, wherein
the film quality alteration process is an electron beam irradiation process.

25. The method for manufacturing a semiconductor device of claim 1, wherein
the film quality alteration process is a heat source exposure process.

26. The method for manufacturing a semiconductor device of claim 1, wherein
the film quality alteration process is a plasma exposure process.

27. The method for manufacturing a semiconductor device of claim 26, wherein
the plasma exposure process uses a mixed gas containing one or more of ammonium, nitrogen, oxygen, helium, argon and hydrogen.

28. The method for manufacturing a semiconductor device of claim 1, wherein
the film quality alteration process is an ion implantation process.

29. The method for manufacturing a semiconductor device of claim 28, wherein
the implantation process uses a mixed gas containing one or more of silane, ammonium, nitrogen, oxygen, helium, argon, hydrogen, nitride trifluoride and carbon tetrafluoride.

30. The method for manufacturing a semiconductor device of claim 1, wherein
the curing process is an ultraviolet irradiation process.

31. The method for manufacturing a semiconductor device of claim 1, wherein
the curing process is an electron beam irradiation process.

32. The method for manufacturing a semiconductor device of claim 1, wherein
the curing process is a heat source exposure process.
